(19) United States
(12) Patent Application Publication
(10) Pub. No.: US 2026/0032852 A1
(43) Pub. Date: Jan. 29, 2026

(54) Fan System for a Portable Information Handling System

(71) Applicant: Dell Products L.P., Round Rock, TX (US)

(72) Inventors: Trevor Todd, San Antonio, TX (US); Mark Andrew Schwager, Cedar Park, TX (US)

(21) Appl. No.: 18/780,576

(22) Filed: Jul. 23, 2024

(51) Int. Cl. H05K 7/20; G06F 1/20

(52) U.S. Cl. CPC H05K 7/20172; H05K 7/20145; G06F 1/203

(57) ABSTRACT

A fan system for an information handing system. The fan system includes a side vent defined by a base chassis; and, a fan component mounted within the base chassis, the fan component comprising a fan housing, the fan housing comprising an inside edge and a base; and, a fan mounted within the fan housing, the fan being mounted within the fan housing at an angle, the angle sloping away from the inside edge of the fan housing, the fan being mounted at the angle causing the fan to tilt relative to a plane defined by the base chassis of the information handling system.

### BACKGROUND OF THE INVENTION

### Field Of The Invention

The present invention relates to information handling systems. More specifically, embodiments of the invention relate to a keyboard assembly for a portable information handling system.

### Description Of The Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY OF THE INVENTION

In one embodiment the invention relates to a fan component for a fan system for an information handing system, comprising: a fan housing, the fan housing comprising an inside edge and a base; and, a fan mounted within the fan housing, the fan being mounted within the fan housing at an angle, the angle sloping away from the inside edge of the fan housing, the fan being mounted at the angle causing the fan to tilt relative to a plane defined by a base chassis of the information handling system.

In another embodiment the invention relates to a fan system for an information handling system comprising a side vent defined by a base chassis; and, a fan component mounted within the base chassis, the fan component comprising a fan housing, the fan housing comprising an inside edge and a base; and, a fan mounted within the fan housing, the fan being mounted within the fan housing at an angle, the angle sloping away from the inside edge of the fan housing, the fan being mounted at the angle causing the fan to tilt relative to a plane defined by the base chassis of the information handling system.

In another embodiment the invention relates to an information handling system comprising: a processor; a data bus coupled to the processor; a base chassis, the base chassis housing the processor, the base chassis defining a side vent; and, a fan system mounted within the base chassis, the fan system comprising a fan component, the fan component comprising a fan housing, the fan housing comprising an inside edge and a base; and, a fan mounted within the fan housing, the fan being mounted within the fan housing at an angle, the angle sloping away from the inside edge of the fan housing, the fan being mounted at the angle causing the fan to tilt relative to a plane defined by the base chassis of the information handling system.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of an example portable information handling system.

FIG. 3 shows a blown-up view of a portable information handling system.

FIG. 4 shows a cut away top view of a base chassis of a portable information handling system.

FIGS. 5A and 5B, generally referred to as FIG. 5, show a plurality of views of a fan system of a portable information handling system.

FIG. 6 shows a cut away bottom perspective view of a portion of a base chassis of a portable information handling system.

FIGS. 7A, 7B, 7C, 7D and 7E, generally referred to as FIG. 7, show a plurality of views of fan components of a fan system of a portable information handling system.

FIGS. 8A, 8B, 8C and 8D, generally referred to as FIG. 8, show example heat distributions and airflows of a portable information handling system having a fan system in accordance with the present disclosure.

### DETAILED DESCRIPTION

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

Various aspects of the present disclosure include an appreciation thermal management for information handling systems such as portable information handling systems is an important aspect of the information handling system design. Various aspects of the present disclosure include an appreciation thermal management for information handling systems often included some form of bottom venting to improve airflow in the information handling systems. Various aspects of the present disclosure include an appreciation that bottom venting often provided the lowest impedance airflow design. Various aspects of the present disclosure include an appreciation that it can be desirable to remove bottom vents from the information handling system thermal management design. Various aspects of the present disclosure include an appreciation without bottom vents, airflow produced from side venting becomes especially important for thermal management.

Various aspects of the present disclosure include an appreciation that side venting can present certain challenges relating to cooling the information handling system. Various aspects of the present disclosure include an appreciation that with a side vented system, inlet air has to travel through system and squeeze between the fan housing and the D-cover of the base chassis to reach an inlet hub of the fan. This issue can impact the Z dimension of the base chassis to ensure inlet airflow impedance is low or can reduce fan system capability. Additionally, with known side vented systems the airflow path is often restricted by the fan inlet air cross section by the gap between the inside of the D cover and the fan inlet on the bottom of the fan. Additionally, with known side vented systems the inlet airflow impedance is often lower than the exhaust air impedance, which can create a bottle neck at the inlet of the fan which can result in an unoptimized position on a fan curve.

A system and method are disclosed for providing an information handling system with a side vent optimized fan system. In certain embodiments, the side vent optimized fan system includes a fan component that is configured with a tilted fan. Such a tilted fan increases an inlet air area thus resulting in lower inlet flow impedance. By lowering the inlet flow impedance, the tilted fan enables fan operation which results in an optimized position on a fan curve. Such a tilted fan provides an optimally shifted air inlet gap between the top and the bottom of the base chassis. Such a tilted fan advantageously enables a locally thin C-cover to D-cover dimension at the edge of the fan apex while gaining additional air inlet gap space. Additionally, such a tilted fan allows a system to be configured with increased internal space outside the edge of the keyboard (thus allowing move available space in the Z dimension) for the tilted fan,

In certain embodiments, the fan axis is tilted inward by approximately 2.5 degrees. In certain embodiments, such a fan tilt increases the cross-sectional area of the fan inlet from 121 sq mm to 191.4 sq mm. So tilting the fan also creates a gap on the system on chip side of the information handling system, thereby providing greater air movement in the system on chip area which reduces skin temperatures at hot spots created by the system on a chip.

In certain embodiments, the fan component is configured to align with a fin stack of the fan system. In certain embodiments, the fan housing outlet is varied (when compared to a fan housing portion) to align with a fin stack of the fan system.

In certain embodiments, the fan system includes a first side fan portion, another side fan portion, or a combination thereof. In certain embodiments, the first side fan portion is positioned to receive airflow from a first side vent. In certain embodiments, the first side fan portion and the first side vent provide a first side thermal solution. In certain embodiments, the another side fan portion is positioned to receive airflow from another side vent. In certain embodiments, the another side fan portion and the another side vent provide another side thermal solution. In certain embodiments, the first side corresponds to a left side of a base chassis of an information handling system. In certain embodiments, the another side corresponds to a right side of a base chassis of an information handling system. As used herein, a thermal solution broadly refers to a design to manage heat produced by components included within the information handling system. In certain embodiments, managing heat includes generating an airflow via which heat generated within the information handling system is externally vented away from the interior of the information handling system.

In certain embodiments, the first side fan portion includes a first side fan component, a first side fin stack, or a combination thereof. In certain embodiments, the first side fan component includes a first side fan housing, a first side tilted fan, or a combination thereof. In certain embodiments, the another side fan portion includes a another side fan component, a another side fin stack, or a combination thereof. In certain embodiments, the another side fan component includes a another side fan housing, a another side tilted fan, or a combination thereof.

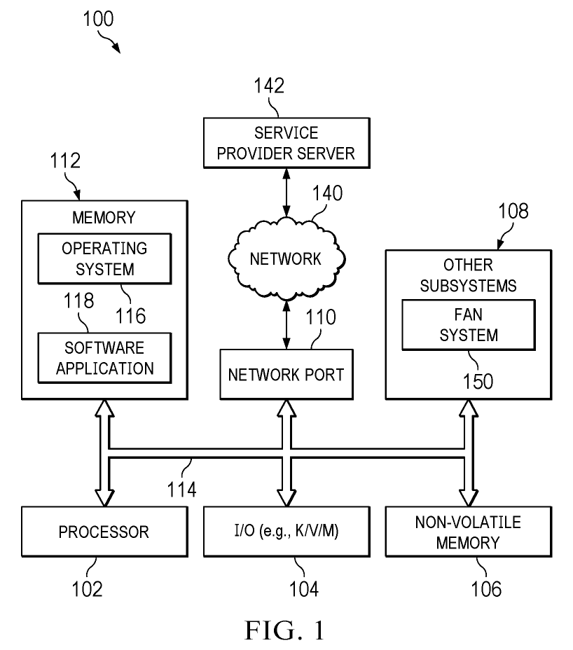

FIG. 1 is a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, a touchpad or touchscreen, and associated controllers, a hard drive or disk storage 106, and various other subsystems 108. In various embodiments, the information handling system 100 also includes network port 110 operable to connect to a network 140, which is likewise accessible by a service provider server 142. The information handling system 100 likewise includes system memory 112, which is interconnected to the foregoing via one or more buses 114. System memory 112 further comprises operating system (OS) 116 and in various embodiments may also comprise at least one software application 118. In one embodiment, the information handling system 100 is able to download the software application from the service provider server 142. In another embodiment, the software application 118 is provided as a service from the service provider server 142.

In certain embodiments, the information handling system includes a fan system 150. In certain embodiments, the fan system 150 includes a side vent optimized fan system. In certain embodiments, the side vent optimized fan system includes a fan component that is configured with a tilted fan. In certain embodiments, the tilted fan increases an inlet air area thus resulting in lower inlet flow impedance. By lowering the inlet flow impedance, the tilted fan enables fan operation which results in an optimized position on a fan curve. Such a tilted fan provides an optimally shifted air inlet gap between the top and the bottom of the base chassis. Such a tilted fan advantageously enables a locally thin C-cover to D-cover dimension at the edge of the fan apex while gaining additional air inlet gap space. Additionally, such a tilted fan allows a system to be configured with increased internal space outside the edge of the keyboard (thus allowing move available space in the Z dimension) for the tilted fan,

In certain embodiments, the fan axis is tilted inward by approximately 2.5 degrees. In certain embodiments, such a fan tilt increases the cross-sectional area of the fan inlet from 121 sq mm to 191.4 sq mm. So tilting the fan also creates a gap on the system on chip side of the information handling system, thereby providing greater air movement in the system on chip area which reduces skin temperatures at hot spots created by the system on a chip.

In certain embodiments, the fan component is configured to align with a fin stack of the fan system. In certain embodiments, the fan housing outlet is varied to align with a fin stack of the fan system.

In certain embodiments, the fan system includes a first side fan portion, another side fan portion, or a combination thereof. In certain embodiments, the first side fan portion is positioned to receive airflow from a first side vent. In certain embodiments, the first side fan portion and the first side vent provide a first side thermal solution. In certain embodiments, the another side fan portion is positioned to receive airflow from another side vent. In certain embodiments, the another side fan portion and the another side vent provide another side thermal solution. In certain embodiments, the first side corresponds to a left side of a base chassis of an information handling system. In certain embodiments, the another side corresponds to a right side of a base chassis of an information handling system.

In certain embodiments, the first side fan portion includes a first side fan component, a first side fin stack, or a combination thereof. In certain embodiments, the first side fan component includes a first side fan housing, a first side tilted fan, or a combination thereof. In certain embodiments, the another side fan portion includes a another side fan component, a another side fin stack, or a combination thereof. In certain embodiments, the another side fan component includes a another side fan housing, a another side tilted fan, or a combination thereof.

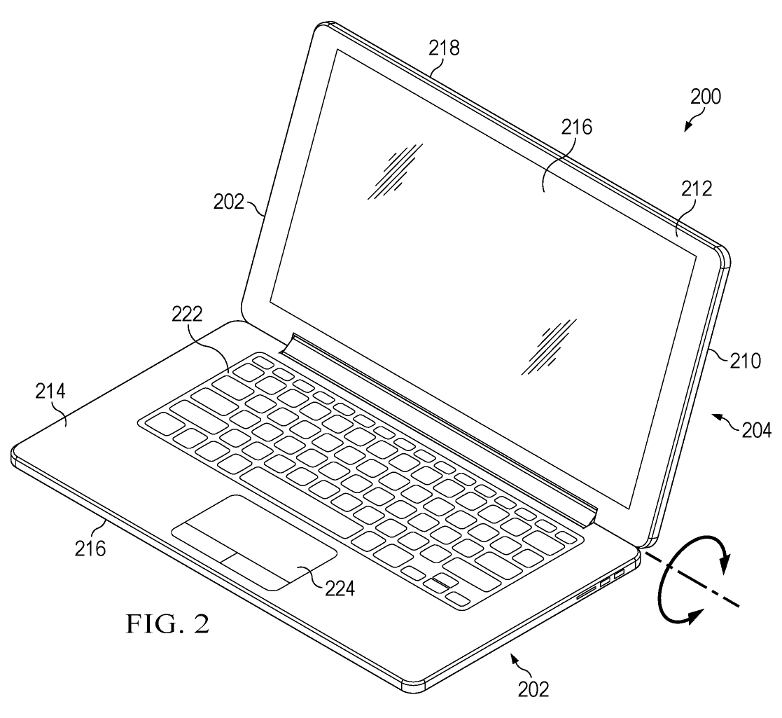

FIG. 2 shows a perspective view of an example portable information handling system chassis 200 such as a tablet type portable information handling system, a laptop type portable information handling system, or any other mobile information handling system. It will be appreciated that some or all of the components of the information handling system 100 may be included within information handling system chassis 200. The portable information handling system 200 chassis includes a base chassis 202 and a display chassis 204 shown in an open configuration. It will be appreciated that a closed configuration would have the display chassis 204 fully closed onto the base chassis 202.

The base chassis 202 or the display chassis 204 of the information handling system 200 may comprise an outer metal case or shell. The information handling system 200 may include a plurality of chassis portions. In various embodiments, the information handling system 200 may include some or all of an A-Cover 210, a B-Cover 212, a C-cover 214 and a D-Cover 216. In various embodiments, the A-Cover 210 and the B-Cover 212 provide the display chassis 204. In various embodiments, the C-Cover 214 and the D-Cover 216 provide the base chassis 202.

In various embodiments, the A-cover 210 encloses a portion of the display chassis 204 of the information handling system 200. In various embodiments, the B-cover 212 encloses another portion of the display chassis 204 of the information handling system 200. In various embodiments, the B-Cover may include a display screen 216 and a bezel 218 around the display screen.

In various embodiments, the C-cover 214 encloses a portion of the base chassis 202 of the information handling system 200. In various embodiments, the C-cover 214 may include, for example, a keyboard 222, a trackpad 224, or other input/output (I/O) device. In various embodiments, certain components of the information handling system such as a mother board are mounted within the C-Cover 214. In various embodiments, the D-cover 216 encloses another portion of the base chassis 202 of the information handling system 200.

When placed in the closed configuration, the A-cover 202 forms a top outer protective shell, or a portion of a lid, for the information handling system 200, while the D-cover 204 forms a bottom outer protective shell, or a portion of a base, for the information handling system. When in the fully closed configuration, the A-cover 202 and the D-cover 204 would be substantially parallel to one another.

In some embodiments, both the A-cover 202 and the D-cover 204 may be comprised entirely of metal. In some embodiments, the A-cover 202 and D-cover 204 may include both metallic and plastic components. For example, plastic components that are radio-frequency (RF) transparent may be used to form a portion of the C-cover 208.

In various embodiments, the A-cover 202 may be movably connected to a back edge of the D-cover 204 via one or more hinges. In this configuration, the hinges allow the A-cover 202 to rotate from and to the D-cover 204 allowing for multiple orientations of the information handling system 200. In various embodiments, the information handling system may include a sensor to detect the orientation of the information handling system and activate or deactivate any number of antenna systems based on the occurrence of any specific orientation. In some embodiments, the information handling system may be a laptop with limited rotation of the A-cover 204 with regard to the D-cover 204, for example up to 180° rotation arc. In other embodiments the information handling system 200 may be a convertible information handling system with full rotation to a tablet configuration.

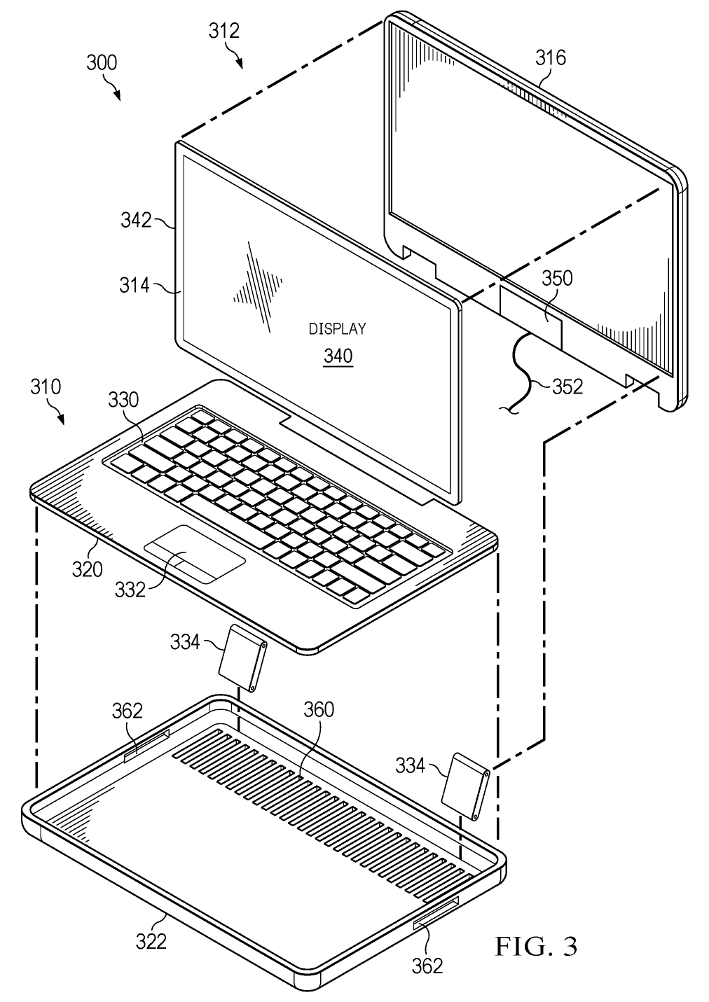

FIG. 3 shows a blown-up view of a portable information handling system 300 having rotationally–coupled housing portions. In the example embodiment, a main housing portion 310 (which corresponds to a base chassis 202) rotationally couples to a lid housing portion 312 (which corresponds to a display chassis 204) to support various configurations to interact with an end user. Main housing portion 310 may hold one or more components of the portable information handling system, including but not limited to processor 102, system bus 114, memory subsystem 112, I/O subsystem 104 and network interface 110 discussed with respect to FIG. 1. Main housing portion 310 includes a top cover portion 320 (which includes the C-Cover 214) and a bottom cover portion 322 (which includes the D-Cover 216). Lid housing portion 312 includes a display cover portion 314 (which includes the B-Cover 210) and a rear display cover portion 316 (which includes the A-Cover 212). The top cover portion 320 may include an integrated keyboard 330 or other I/ O devices, such as a trackpad 332 or microphone (not shown). In various embodiments, the keyboard 330 may be mounted to the top of the C-Cover of the main housing portion 310. In various embodiments, the keyboard 330 may be mounted to the underside of the C-Cover of the main housing portion 310.

Lid housing portion 312 is rotationally coupled to main housing portion 310 via at least one hinge assembly 334. Lid housing portion 212 includes display 340 that visually presents information to the user as well as a bezel 342. Display 340 may be a touch panel with circuitry enabling touch functionality in conjunction with a display. In some embodiments, display 340 may be an “infinity edge” or “narrow bezel” display that approaches one or more the edges of lid housing portion 212 such that bezel may be narrow in size ( e. g., less than 10 millimeters ) on the edges. For example, display 340 is an infinity display with narrow bezels on the top and sides of lid housing portion 212 in the embodiment shown in FIG. 3. In certain embodiments, the side bezel is less than 4 mm (+/-10%) and the top bezel is less than 6 mm (+/-10%).

Lid housing portion 312 may also include timing controller (TCON) 350. Hinge assembly 330 may include cable 352 for communicably coupling one or more components within main housing portion 310 to one or more components within lid housing portion 312. For example, cable 352 may provide communication of graphics information from an I/O subsystem to TCON 350 for generation of visual images for display on display 340. Although a single cable 352 is shown, portable information handling system 300 may include one or more additional cables 352 for communicating components disposed in main housing portion 310 and lid housing portion 312. Placement of cable 352 may be selected based on design considerations, materials or manufacturing cost, material reliability, antenna placement, as well as any other considerations.

Hinge assembly 334 allows main housing portion 310 and lid housing portion 312 to rotate between a plurality of positions. For example, when portable information handling system 300 is not in use, lid housing portion 312 may be closed over the top of main portion 310 such that display 340 and keyboard 330 are protected from unintended use or damage. Rotation of lid housing portion 312 by approximately 90 degrees from main housing portion 310 brings display 340 in a raised “ clamshell ” position relative to keyboard 330 so that an end user can make inputs to keyboard 330 or touch panel portion of display 340 while viewing display 340. In some embodiments, clamshell position may represent lid housing portion 212 open between approximately 1 and 180 degrees from main housing portion 310. Rotation of lid housing portion 312 between approximately 180 and 359 degrees from main housing portion 310 may place portable information handling system 300 in “tablet stand” and /or “tent” positions. In tablet stand and tent positions, the user may make inputs via touch panel portion of display 340 while viewing display 340. A full 360 degree rotation of main housing portion 310 relative to lid housing portion 312 provides a tablet configuration having display 340 exposed to accept touch inputs. In any position, user inputs may be communicated to an I/O subsystem or a processor of the portable information handling system 300 for processing, and then updated information may be communicated back via cable 352 to display 340 for displaying to the user. Hinge assembly 334 may be comprised of one or more discrete hinges or a unified assembly of hinges.

In certain embodiments, the main housing portion 310 includes a fan system 360. In certain embodiments, the fan system 360 includes a side vent optimized fan system. In certain embodiments, the fan system 360 corresponds to fan system 150. In certain embodiments, the fan system 360 includes one or more side vents 362 defined by the bottom cover portion 322.

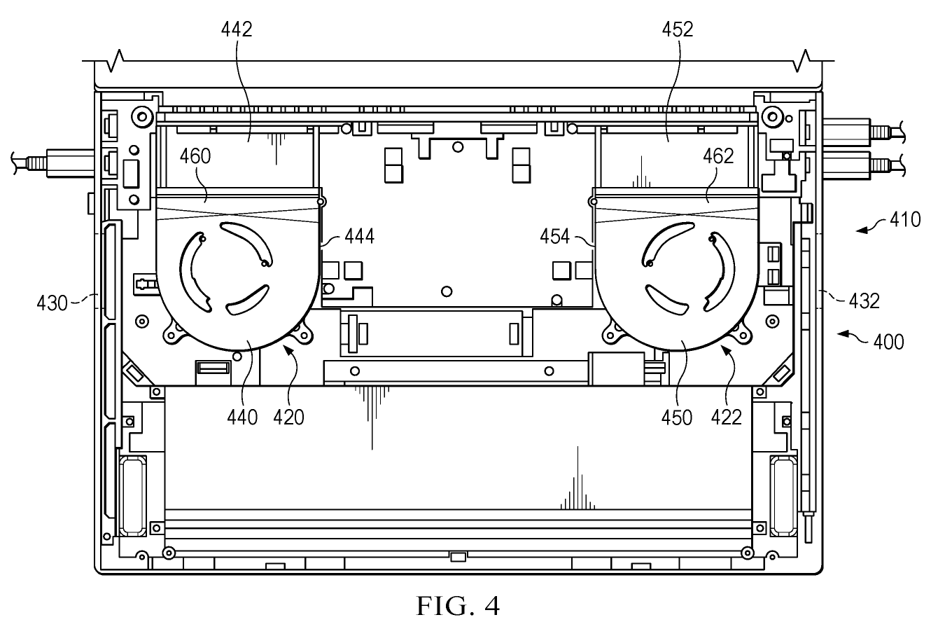

FIG. 4 shows a cut away top view of a base chassis 400 of a portable information handling system. In certain embodiments, the base chassis 400 includes a fan system 410. In certain embodiments, the fan system 410 corresponds to fan system 150.

In certain embodiments, the fan system 410 includes a first side fan portion 420, another side fan portion 422, or a combination thereof. In certain embodiments, the first side fan portion 420 is positioned to receive airflow from a first side vent 430. In certain embodiments, the first side fan portion 420 and the first side vent 430 provide a first side thermal solution. In certain embodiments, the another side fan portion 422 is positioned to receive airflow from another side vent 432. In certain embodiments, the another side fan portion 422 and the another side vent 432 provide another side thermal solution. In certain embodiments, the first side corresponds to a left side of a base chassis of an information handling system. In certain embodiments, the another side corresponds to a right side of a base chassis of an information handling system.

In certain embodiments, the first side fan portion 420 includes a first side fan component 440, a first side fin stack 442, or a combination thereof. In certain embodiments, the first side fan component 440 includes a first side fan housing 444, a first side tilted fan, or a combination thereof. In certain embodiments, the first fan component 420 is configured to align with the first side fin stack 442. In certain embodiments, a first fan component fan housing outlet 460 is configured to align with the first side fin stack 442.

In certain embodiments, the first side tilted fan increases an inlet air area thus resulting in lower inlet flow impedance. By lowering the inlet flow impedance, the tilted fan enables fan operation which results in an optimized position on a fan curve. In certain embodiments, the first side tilted fan has a fan axis which tilted inward by substantially (i.e., +/- 15%) 2.5 degrees. In certain embodiments, such a fan tilt increases the cross-sectional area of the fan inlet from 121 sq mm to 191.4 sq mm. so tilting the fan also creates a gap on the system on chip side of the information handling system, thereby providing greater air movement in the system on chip area which reduces skin temperatures at hot spots created by the system on a chip.

In certain embodiments, the another side fan portion 422 includes an another side fan component 450, an another side fin stack 452, or a combination thereof. In certain embodiments, the another side fan component 450 includes an another side fan housing 454, an another side tilted fan, or a combination thereof. In certain embodiments, the another fan component 422 is configured to align with the another side fin stack 452. In certain embodiments, an another fan component fan housing outlet 462 is configured to align with the another side fin stack 452.

In certain embodiments, the another side tilted fan increases an inlet air area thus resulting in lower inlet flow impedance. By lowering the inlet flow impedance, the tilted fan enables fan operation which results in an optimized position on a fan curve. In certain embodiments, the another side tilted fan has a fan axis which tilted inward by substantially (i.e., +/- 15%) 2.5 degrees. In certain embodiments, such a fan tilt increases the cross-sectional area of the fan inlet from 121 sq mm to 191.4 sq mm. so tilting the fan also creates a gap on the system on chip side of the information handling system, thereby providing greater air movement in the system on chip area which reduces skin temperatures at hot spots created by the system on a chip.

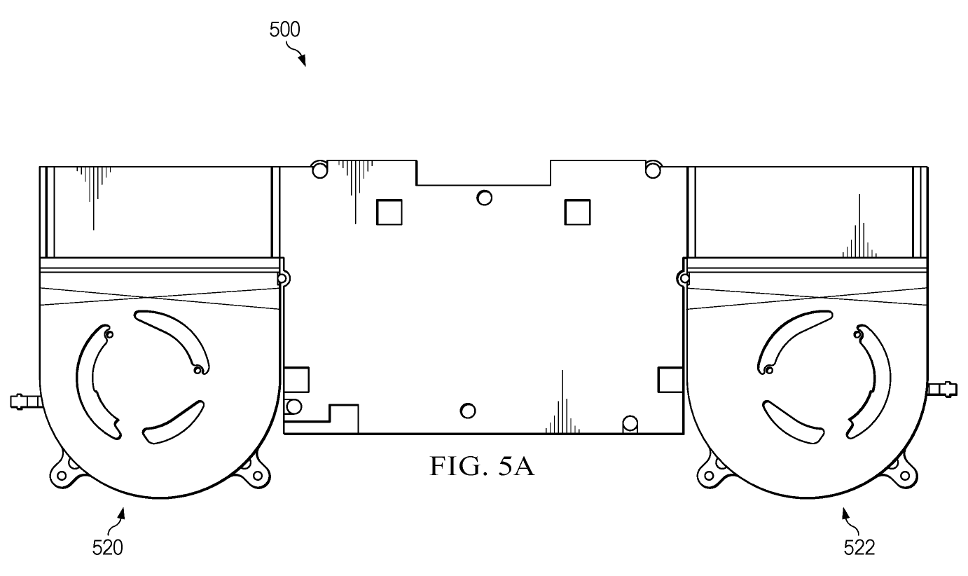

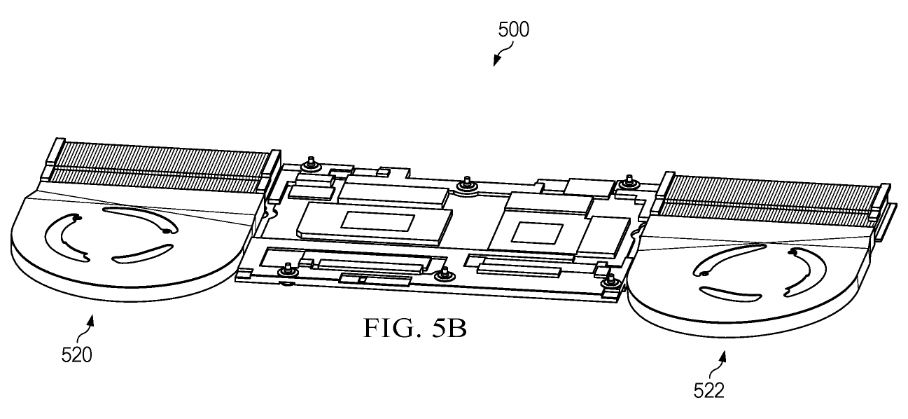

FIGS. 5A and 5B, generally referred to as FIG. 5, show a plurality of views of a fan system 500 of a portable information handling system. More specifically, FIG. 5A shows a top view of a fan system 500. FIG. 5B shows a perspective view of a fan system 500. In certain embodiments, the fan system 500 corresponds to fan system 150.

In certain embodiments, the fan system 500 includes a first side fan portion 520, another side fan portion 522, or a combination thereof. In certain embodiments, the first side fan portion 520 is positioned to receive airflow from a first side vent. In certain embodiments, the another side fan portion 522 is positioned to receive airflow from another side vent. In certain embodiments, the first side corresponds to a left side of a base chassis of an information handling system. In certain embodiments, the another side corresponds to a right side of a base chassis of an information handling system.

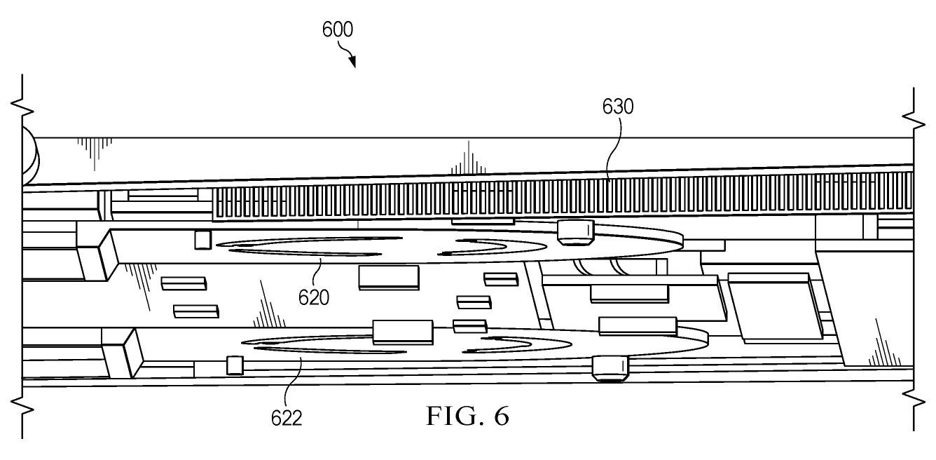

FIG. 6 shows a cut away bottom perspective view of a portion of a base chassis of a portable information handling system. In certain embodiments, the base chassis 600 includes a fan system 605. In certain embodiments, the fan system 605 corresponds to fan system 150.

In certain embodiments, the fan system 600 includes a first side fan portion 620, another side fan portion 622, or a combination thereof. In certain embodiments, the first side fan portion 620 is positioned to receive airflow from a first side vent 630. In certain embodiments, the another side fan portion 622 is positioned to receive airflow from another side vent (not shown in FIG. 6). In certain embodiments, the first side corresponds to a left side of a base chassis of an information handling system. In certain embodiments, the another side corresponds to a right side of a base chassis of an information handling system.

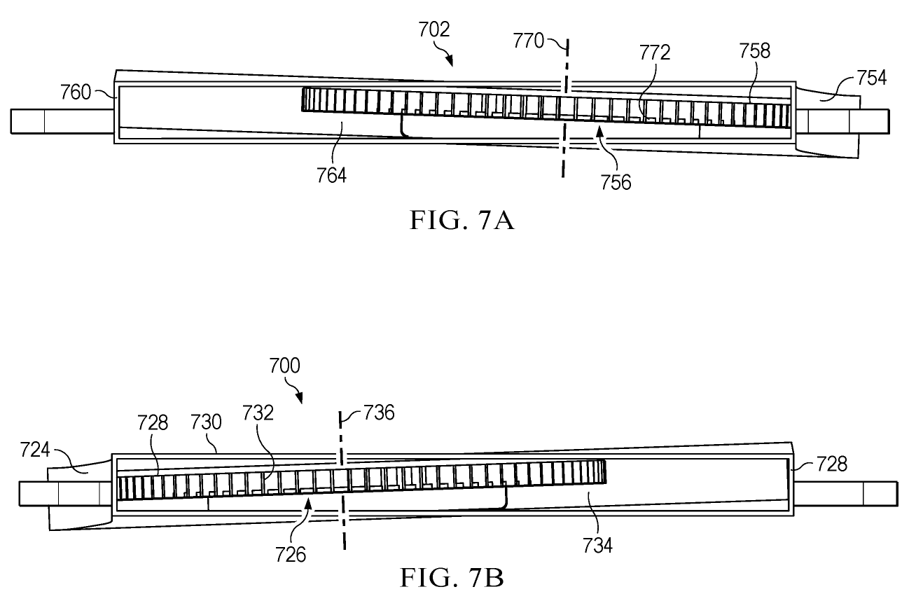

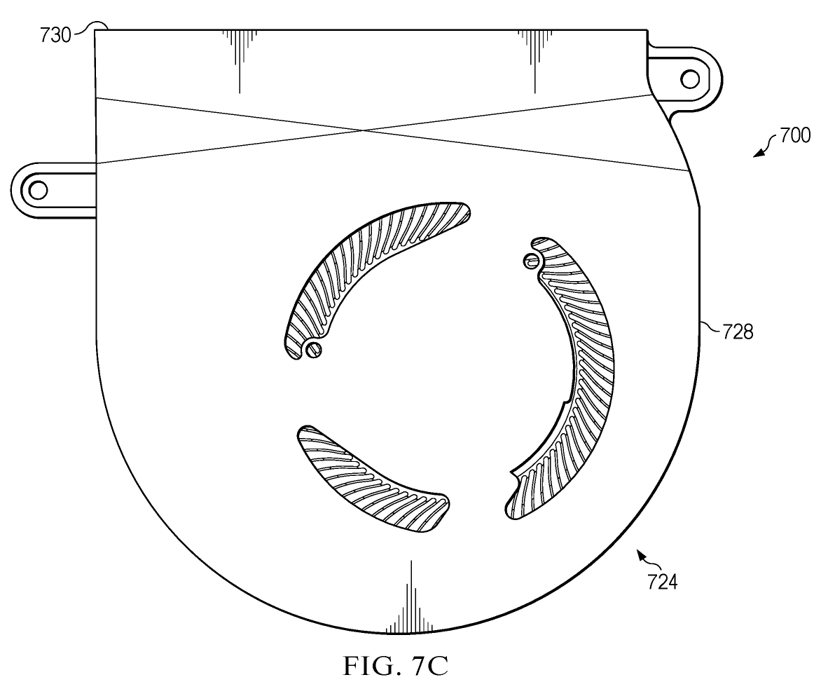

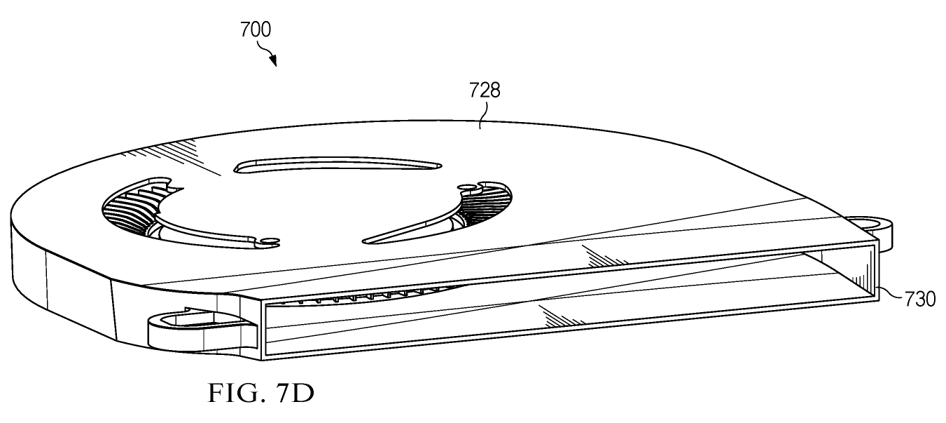

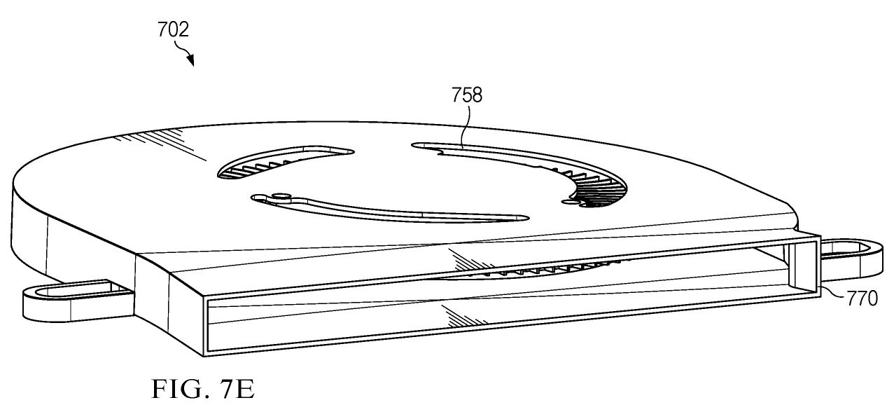

FIGS. 7A, 7B, 7C, 7D and 7E, generally referred to as FIG. 7, show a plurality of views of fan components of a fan system of a portable information handling system. More specifically, FIG. 7A shows a cut away side view of a first fan component 700. FIG. 7B shows a cut away side view of another fan component 702. FIG. 7C shows a top view of a fan component 700. FIG. 7D shows a perspective view of a fan component 700. FIG. 7E shows a perspective view of another fan component 702. In certain embodiments, the fan component 700 corresponds to first side fan component 740. In certain embodiments, the fan component 702 corresponds to another side fan component 742.

In certain embodiments, the first side fan component 700 includes a first side fan housing 724, a first side tilted fan 726, or a combination thereof. In certain embodiments, the first fan component 700 is configured to align with a first side fin stack. In certain embodiments, the first side fan housing 724 includes a first side fan housing portion 728, a first side fan housing outlet 730, or a combination thereof. In certain embodiments, the first side housing portion 728 includes an inside edge, a base, a top, or a combination thereof. In certain embodiments, the first side fan component fan housing outlet 730 is configured to align with a first side fin stack.

In certain embodiments, the first side tilted fan 726 increases an inlet air area thus resulting in lower inlet flow impedance. By lowering the inlet flow impedance, the tilted fan enables fan operation which results in an optimized position on a fan curve. In certain embodiments, the first side tilted fan has a fan axis 730 which tilted inward by substantially (i.e., +/- 15%) 2.5 degrees. By tilting the fan about the fan axis 730, the fan 726 is mounted within the fan housing 724 at an angle. Accordingly, blades 732 of the fan 726 rotate about the axis 730 at an angle which is defined by the angle in which the fan 724 is mounted within the fan housing 726. In certain embodiments, such a fan tilt increases a cross-sectional area of 734 the fan inlet. In certain embodiments, such a fan tilt increases a cross-sectional area of 734 the fan inlet from 121 sq mm to 191.4 sq mm. so tilting the fan also creates a gap on the system on chip side of the information handling system, thereby providing greater air movement in the system on chip area which reduces skin temperatures at hot spots created by the system on a chip.

In certain embodiments, the first side fan housing portion 726 is configured at an angle to provide the first side fan housing portion 726 with a tilt, the angle substantially corresponding to the tilt of the fan. In certain embodiments, the first side fan housing outlet 730 is substantially flat relative to the angle of tilt of the fan housing,

In certain embodiments, the another side fan component 702 includes an another side fan housing 754, an another side tilted fan 756, or a combination thereof. In certain embodiments, the another fan component 702 is configured to align with another side fin stack. In certain embodiments, the another side fan housing 754 includes an another side fan housing portion 758, an another side fan housing outlet 770, or a combination thereof. In certain embodiments, the another side housing portion 758 includes an inside edge, a base, a top, or a combination thereof. In certain embodiments, the another side fan housing outlet 770 is configured to align with a first side fin stack.

In certain embodiments, the another side tilted fan 756 increases an inlet air area thus resulting in lower inlet flow impedance. By lowering the inlet flow impedance, the tilted fan enables fan operation which results in an optimized position on a fan curve. In certain embodiments, the another side tilted fan has a fan axis 770 which tilted inward by substantially (i.e., +/- 15%) 2.5 degrees. By tilting the fan about the fan axis 770, the fan 756 is mounted within the fan housing 754 at an angle. Accordingly, blades 772 of the fan 756 rotate about the axis 760 at an angle which is defined by the angle in which the fan 754 is mounted within the fan housing portion 758. In certain embodiments, such a fan tilt increases a cross-sectional area of 764 the fan inlet. In certain embodiments, such a fan tilt increases a cross-sectional area of 764 the fan inlet from 121 sq mm. to 191.4 sq mm. so tilting the fan also creates a gap on the system on chip side of the information handling system, thereby providing greater air movement in the system on chip area which reduces skin temperatures at hot spots created by the system on a chip.

In certain embodiments, the another side fan housing portion 756 is configured at an angle to provide the another side fan housing portion 756 with a tilt, the angle substantially corresponding to the tilt of the fan. In certain embodiments, the another side fan housing outlet 770 is substantially flat relative to the angle of tilt of the fan housing,

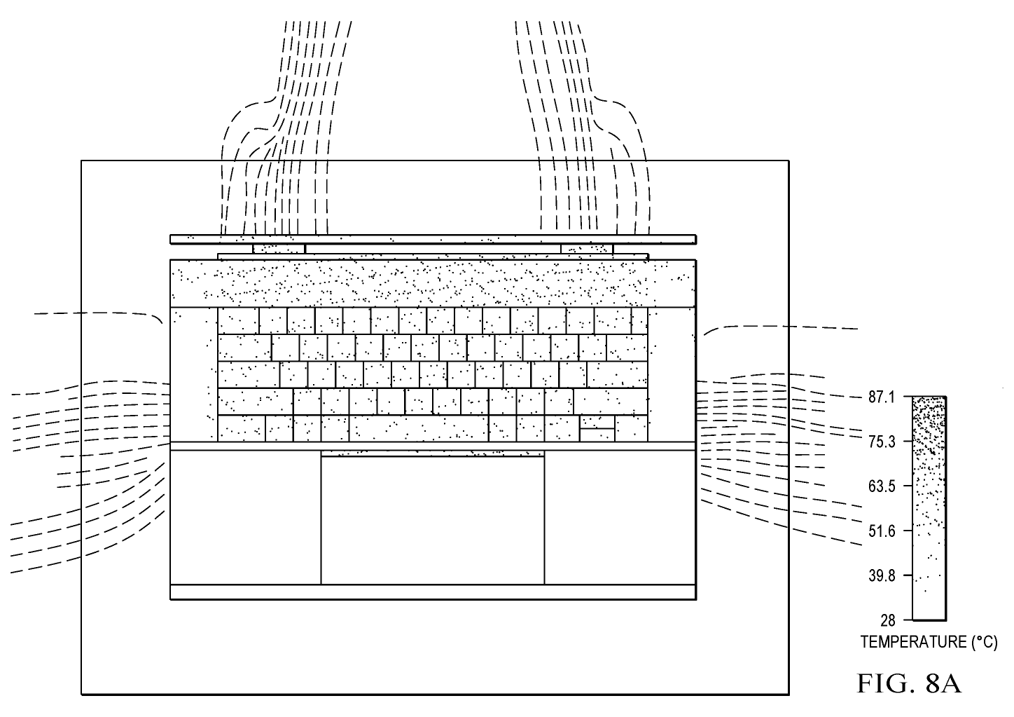

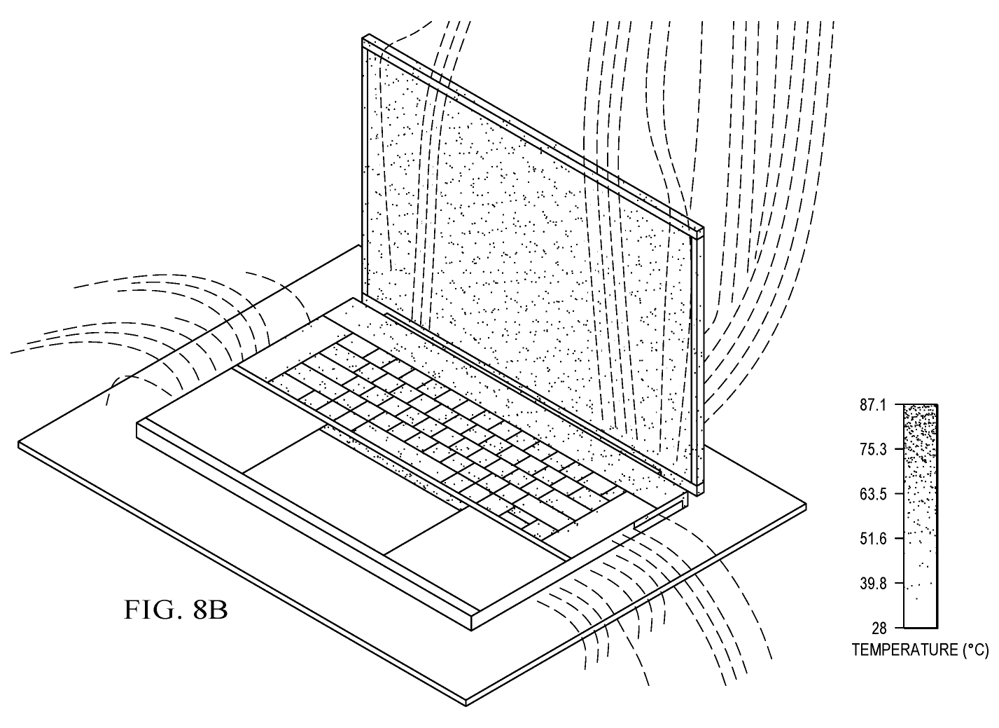

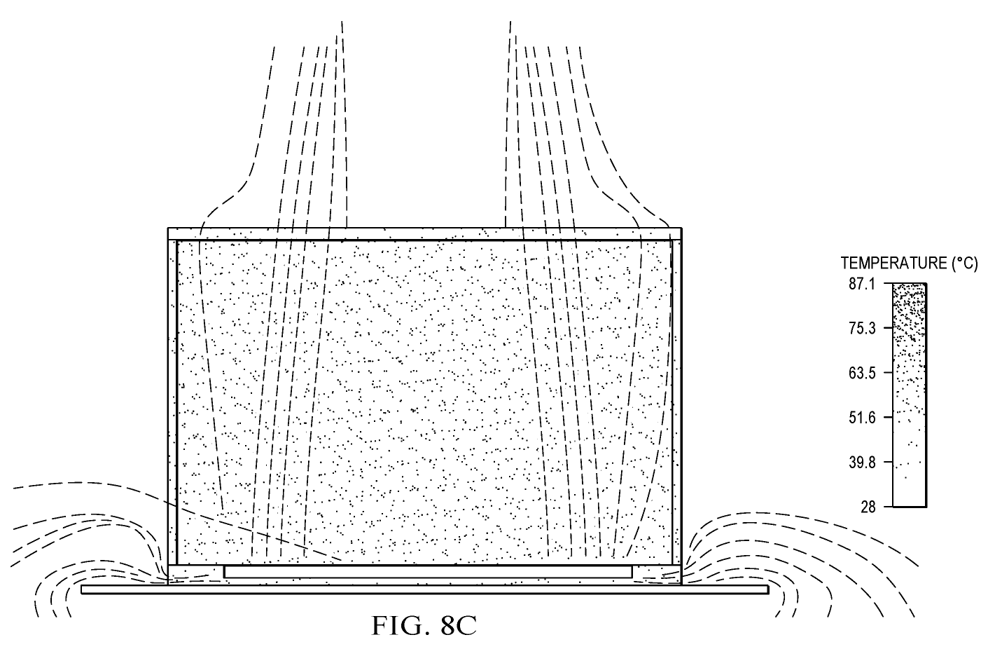

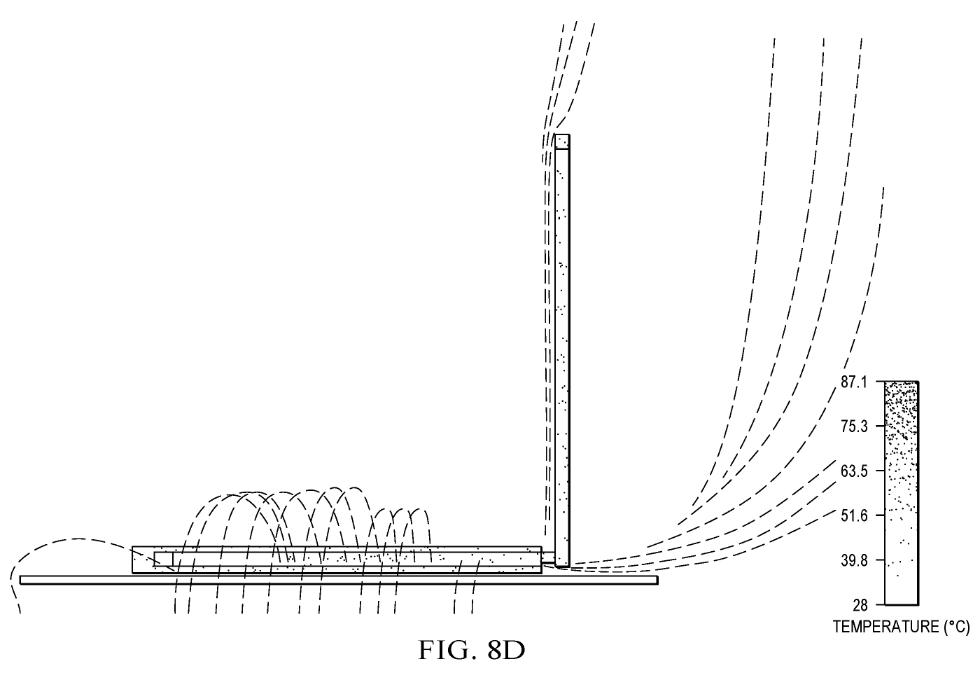

FIGS. 8A, 8B, 8C and 8D, generally referred to as FIG. 8, show example heat distributions and airflows of a portable information handling system having a fan system in accordance with the present disclosure. More specifically, FIG. 8A shows a top view of an information handling system with example heat distributions and airflows produced by a fan system in accordance with the present disclosure. FIG. 8B shows a bottom view of an information handling system with example heat distributions and airflows produced by a fan system in accordance with the present disclosure. FIG. 8C shows a perspective view of an information handling system with example heat distributions and airflows produced by a fan system in accordance with the present disclosure. FIG. 8D shows a side view of an information handling system with example heat distributions and airflows produced by a fan system in accordance with the present disclosure.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only and are not exhaustive of the scope of the invention.

Consequently, the invention is intended to be limited only by the spirit and scope of the appended claims, giving full cognizance to equivalents in all respects.

What is claimed is:

1. A fan component for a fan system for an information handing system, comprising:
a fan housing, the fan housing comprising an inside edge and a base; and,
a fan mounted within the fan housing, the fan being mounted within the fan housing at an angle, the angle sloping away from the inside edge of the fan housing, the fan being mounted at the angle causing the fan to tilt relative to a plane defined by a base chassis of the information handling system.

2. The fan component of claim 1, wherein:
the fan housing includes a fan housing outlet, the fan housing outlet being configured to align with a fin stack of the fan system.

3. The fan component of claim 2, wherein:
the fan housing includes a fan housing portion, the fan housing portion being configured at an angle corresponding to the tilt of the fan; and,
the fan housing outlet is substantially flat relative to the angle of the fan housing portion of the fan housing.

4. The fan component of claim 1, wherein:
the angle is substantially 2.5 degrees.

5. The fan component of claim 1, wherein:
the fan component is configured to receive airflow from a side vent of the base chassis of the information handling system.

6. The fan component of claim 5, wherein:
the fan component and the side vent provide a thermal solution to the information handing system.

7. A fan system for an information handing system comprising:
a side vent defined by a base chassis; and,
a fan component mounted within the base chassis, the fan component comprising
a fan housing, the fan housing comprising an inside edge and a base; and,
a fan mounted within the fan housing, the fan being mounted within the fan housing at an angle, the angle sloping away from the inside edge of the fan housing, the fan being mounted at the angle causing the fan to tilt relative to a plane defined by the base chassis of the information handling system.

8. The fan system of claim 7, wherein:
the fan system further includes a fin stack; and,
the fan housing includes a fan housing outlet, the fan housing outlet being configured to align with the fin stack of the fan system.

9. The fan system of claim 7, wherein:
the fan housing includes a fan housing portion, the fan housing portion being configured at an angle corresponding to the tilt of the fan; and,
the fan housing outlet is substantially flat relative to the angle of the fan housing portion of the fan housing.

10. The fan system of claim 7, wherein:
the angle is substantially 2.5 degrees.

11. The fan system of claim 7, wherein:
the fan component is configured to receive airflow from the side vent of the base chassis of the information handling system.

12. The fan system of claim 5, wherein:
the fan component and the side vent provide a thermal solution to the information handing system.

13. An information handling system comprising:
a processor;
a data bus coupled to the processor;
a base chassis, the base chassis housing the processor, the base chassis defining a side vent; and,
a fan system mounted within the base chassis, the fan system comprising a fan component, the fan component comprising
a fan housing, the fan housing comprising an inside edge and a base; and,
a fan mounted within the fan housing, the fan being mounted within the fan housing at an angle, the angle sloping away from the inside edge of the fan housing, the fan being mounted at the angle causing the fan to tilt relative to a plane defined by the base chassis of the information handling system.

14. The information handling system of claim 13, wherein:
the fan housing includes a fan housing outlet, the fan housing outlet being configured to align with a fin stack of the fan system.

15. The information handling system of claim 14, wherein:
the fan housing includes a fan housing portion, the fan housing portion being configured at an angle corresponding to the tilt of the fan; and,
the fan housing outlet is substantially flat relative to the angle of the fan housing portion of the fan housing.

16. The information handling system of claim 13, wherein:
the angle is substantially 2.5 degrees.

17. The information handling system of claim 13, wherein:
the fan component is configured to receive airflow from a side vent of the base chassis of the information handling system.

18. The information handling system of claim 17, wherein:
the fan component and the side vent provide a thermal solution to the information handing system.
